(19) United States
(12) Patent Application Publication
(10) Pub. No.: US 2009/0274830 A1
(43) Pub. Date: Nov. 5, 2009

(54) ROLL TO ROLL OLED PRODUCTION SYSTEM

(75) Inventors: JOHN M. WHITE, Hayward, CA (US); Takehara TAKAKO, Hayward, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/431,455

(22) Filed: Apr. 28, 2009

Related U.S. Application Data
(60) Provisional application No. 61/049,032, filed on Apr. 30, 2008.

(51) Int. Cl. B05D 5/12; B05C 5/00; C23C 16/54

(52) U.S. Cl. 427/66; 118/300; 118/718

(57) ABSTRACT

The present invention generally relates to a method and an apparatus for processing one or more substrates on a roll to roll system. The one or more substrates may pass through several processing chambers to deposit the layers necessary to produce an OLED structure. The processing chambers may include ink jetting chambers, chemical vapor deposition (CVD) chambers, physical vapor deposition (PVD) chambers, and annealing chambers. Additional chambers may also be present.

### CROSS-REFERENCE TO RELATED APPLICATIONS

This application claims benefit of U.S. provisional patent application Ser. No. 61/049,032 (APPM/012766L), filed Apr. 30, 2008, which is herein incorporated by reference.

### BACKGROUND OF THE INVENTION

1. Field of the Invention

Embodiments of the present invention generally relate to a roll to roll processing apparatus for organic light emitting diode, which may be referred to as organic light emitting display (OLED) manufacturing.

2. Description of the Related Art

OLEDs have gained significant interest recently in display applications in view of their faster response times, larger viewing angles, higher contrast, lighter weight, lower power, and amenability to flexible substrates, as compared to liquid crystal displays (LCD). In addition to organic materials used in OLEDs, many polymer materials are also developed for small molecule, flexible organic light emitting diode, sometimes referred to as flexible organic light emitting displays (FOLED) and polymer light emitting diode, sometimes referred to as polymer light emitting displays (PLED). Many of these organic and polymer materials are flexible for the fabrication of complex, multi-layer devices on a range of substrates, making them ideal for various transparent multi-color display applications, such as thin flat panel display (FPD), electrically pumped organic laser, and organic optical amplifier.

Over the years, layers in display devices have evolved into multiple layers with each layer serving a different function. Depositing multiple layers onto multiple substrates may require multiple processing chambers. Transferring multiple substrates through multiple processing chambers may decrease substrate throughput. Therefore, there is a need in the art for an efficient method and apparatus for processing OLED structures to ensure substrate throughput is maximized and substrate transferring is decreased.

### SUMMARY OF THE INVENTION

The present invention generally relates to methods and apparatus for processing one or more substrates on a roll to roll system. The substrates may pass through several processing chambers to deposit the layers necessary to produce an OLED structure. The processing chambers may include ink jetting chambers, chemical vapor deposition (CVD) chambers, physical vapor deposition (PVD) chambers, and annealing chambers. Additional chambers may also be present.

In one embodiment, an organic light emitting diode manufacturing apparatus comprises a roll to roll substrate feed and retrieval system, one or more inkjet deposition systems through which the substrate passes while on the roll to roll substrate feed and retrieval system, and one or more encapsulating deposition systems through which the substrate passes while on the roll to roll substrate feed and retrieval system.

In another embodiment, an organic light emitting diode manufacturing apparatus comprises a substrate feed roll, a plurality of processing chambers, and a substrate retrieval roll, wherein the processing chambers are coupled together as a substrate is extended between the feed roll and the retrieval roll.

In another embodiment, an organic light emitting diode manufacturing method comprises unrolling a substrate from a first roll, passing the substrate through a hole injection layer deposition apparatus and depositing a hole injection layer over the substrate, passing the substrate through an emissive layer deposition apparatus and depositing an emissive layer over the hole injection layer, and rolling the substrate onto a second roll.

In another embodiment, an organic light emitting diode manufacturing method comprises depositing a hole injection layer over a substrate in a first deposition apparatus, and depositing an emissive layer over the hole injection layer in a second deposition apparatus separate from the first deposition apparatus while the substrate is still disposed in the first deposition apparatus.

In another embodiment, an organic light emitting diode manufacturing method comprises depositing a hole injection layer over a substrate, and depositing an emissive layer over the hole injection layer while the hole injection layer is being deposited over the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an OLED structure according to one embodiment of the invention.

FIG. 2 is a roll to roll coating system according to one embodiment of the invention.

FIG. 3 is a roll to roll coating system according to another embodiment of the invention.

FIG. 4 is a roll to roll coating system according to another embodiment of the invention.

FIG. 5 is a roll to roll coating system according to another embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally relates to methods and apparatus for processing one or more substrates on a roll to roll system. The substrates may pass through several processing chambers to deposit the layers necessary to produce an OLED structure. The processing chambers may include ink jetting chambers, CVD chambers, PVD chambers, and annealing chambers. Additional chambers may also be present.

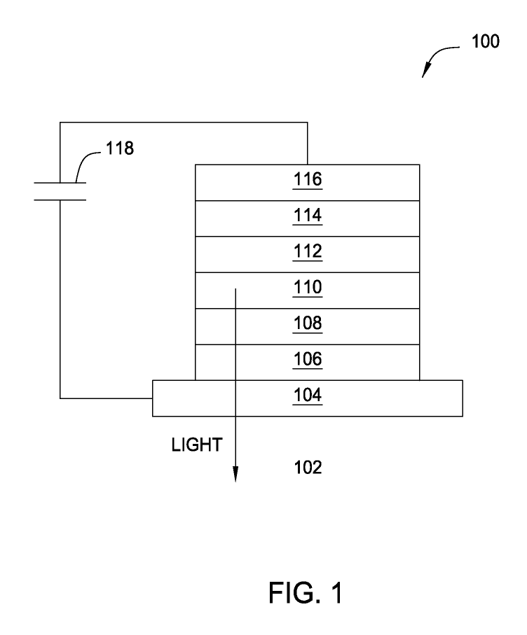

FIG. 1 is an OLED structure 100 according to one embodiment of the invention. The structure 100 comprises a substrate 102. In one embodiment, the substrate 102 is a flexible, roll to roll substrate. It is to be understood that while the substrate 102 is described as a roll to roll substrate, other substrates may be utilized to produce OLEDs including soda lime glass substrates, silicon substrates, semiconductor wafers, polygonal substrates, large area substrates, and flat panel display substrates.

Over the substrate 102, an anode 104 may be deposited. In one embodiment, the anode 104 may comprise a metal such as chromium, copper, or aluminum. In another embodiment, the anode 104 may comprise a transparent material such as zinc oxide, indium-tin oxide, etc. The anode 104 may have a thickness between about 200 Angstroms and about 2000 Angstroms.

A hole injection layer 106 may then be deposited over the anode 104. The hole injection layer 106 may have a thickness between about 200 Angstroms and about 2000 Angstroms. In one embodiment, the hole injection layer 106 may comprise a material having a straight chain oligomer having a phenylenediamine structure. In another embodiment, the hole injection layer 106 may comprise a material having a branched chain oligomer having a phenylenediamine structure.

A hole transport layer 108 may be deposited over the hole injection layer 106. The hole transport layer 108 may have a thickness between about 200 Angstroms to about 1000 Angstroms. The hole transport layer 108 may comprise a diamine. In one embodiment, the hole transport layer 108 comprises a naphthyl-substituted benzidine (NPB) derivative. In another embodiment, the hole transport layer 108 comprises N, N′-diphenyl-N, N′-bis(3-methylphenyl)-(1,1′-biphenyl)-4,4′-diamine (TPD).

An emissive layer 110 may be deposited over the hole transport layer 108. The emissive layer 110 may be deposited to a thickness between about 200 Angstroms to about 1500 Angstroms. Materials for the emissive layer 110 typically belong to a class of fluorescent metal chelated complexes. In one embodiment, the emissive layer comprises 8-hydroxyquinoline aluminum (Alq₃).

An electron transport layer 112 may be deposited over the emissive layer 110. The electron transport layer 112 may comprise metal chelated oxinoid compounds. In one embodiment, the electron transport layer 112 may comprise chelates of oxine itself (also commonly referred to as 8-quinolinol or 8-hydroxyquinoline). The electron transport layer 112 may have a thickness between about 200 Angstroms to about 1000 Angstroms.

An electron injection layer 114 may be deposited over the electron transport layer 112. The electron injection layer 114 may have a thickness between about 200 Angstroms to about 1000 Angstroms. The electron injection layer 114 may comprise a mixture of aluminum and at least one alkali halide or at least one alkaline earth halide. The alkali halides may be selected from the group consisting of lithium fluoride, sodium fluoride, potassium fluoride, rubidium fluoride, and cesium fluoride, and suitable alkaline earth halides are magnesium fluoride, calcium fluoride, strontium fluoride, and barium fluoride.

A cathode 116 may be deposited over the electron injection layer 114. The cathode 116 may comprise a metal, a mixture of metals, or an alloy of metals. In one embodiment, the cathode 116 may comprise an alloy of magnesium (Mg), silver (Ag), and aluminum (Al). The cathode 116 may have a thickness between about 1000 Angstroms and about 3000 Angstroms. An electrical bias may be supplied to the OLED structure 100 by a power source 118 such that light will be emitted and viewable through the substrate 102. The organic layers of the OLED structure 100 comprise the hole injection layer 106, the hole transport layer 108, the emissive layer 110, the electron transport layer 112, and the electron injection layer 114. It should be noted that not all five layers of organic layers are needed to build an OLED structure. For example, in some cases, only the hole transport layer 108 and the emissive layer 110 are needed.

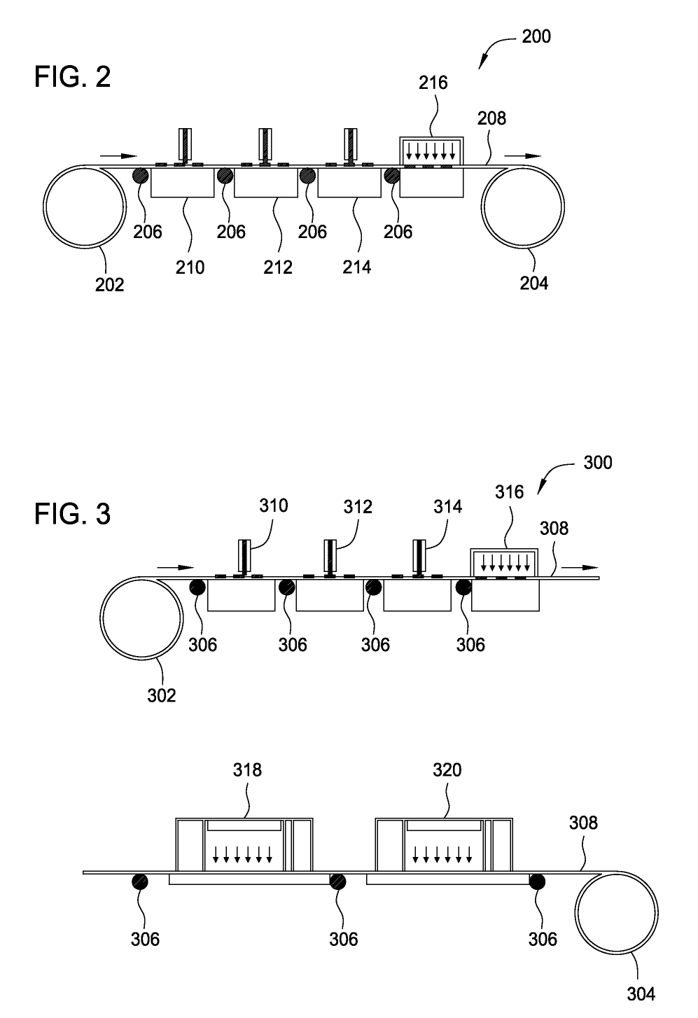

FIG. 2 is a roll to roll coating system 200 according to one embodiment of the invention. The system 200 comprises a first roll 202 that delivers the substrate 208 to the system 200. The substrate passes over one or more rollers 206 and through one or more chambers 210, 212, 214, and 216 to a take-up roll 204 where the substrate 208 is wound. Prior to unrolling the substrate 208 into the system 200, the substrate 208 may have been pretreated or had other processes performed thereon. For example, the backplane of the OLED may have been formed on the substrate 208.

In the system shown in FIG. 2, the substrate 208 is initially unwound from the first roll 202. The substrate passes over a roller 206 before entering into the first chamber 210. Within the first chamber 210, nano-imprinting and/or laser ablation and/or high resolution patterning of the substrate 208 may occur to create an isolation bank on the substrate 208. The isolation bank on the substrate 208 permits multiple OLED structures to be produced upon the same substrate 208.

After passing through the first chamber 210, the substrate 208 passes over another roller 206 and into a second chamber 212. The second chamber 212 may comprise an inkjet chamber. Within the second chamber 212, an anode, a hole injection layer, and/or a hole transport layer may be deposited. Of course, it is to be understood that other layers may be deposited within the second chamber 212 and other processes may be performed in the second chamber 212.

After passing through the second chamber 212, the substrate 208 passes over a roller 206 and enters a third chamber 214. An emissive layer may be deposited in the third chamber 214. In one embodiment, the third chamber 214 may comprise an inkjet chamber. Of course, it is to be understood that other layers may be deposited within the third chamber 214 and other processes may be performed in the third chamber 214.

After passing through the third chamber 214, the substrate 208 passes over another roller 206 and into the fourth chamber 216. Within the fourth chamber, the OLED structure, and in particular the emissive layer, may be cured. In one embodiment, the curing may comprise baking the OLED structure. It is to be understood that other layers may be deposited within the fourth chamber 216 and other processes may be performed in the fourth chamber 216.

After exiting the fourth chamber 216, the substrate 208 may be wound up on the take-up roll 204. The take-up roll 204 with the substrate 208 wound therearound may then be taken to another system for further processing if desired. In so doing, the take-up roll 204 would become the first roll in the next system.

In the roll to roll system 200, the substrate 208 may be disposed within all of the chambers 210, 212, 214, and 216 simultaneously and have the processes that are performed in the chambers 210, 212, 214, and 216 performed simultaneously. For example, if a hole transport layer is deposited on the substrate 208 in the second chamber 212, the emissive layer may be simultaneously deposited thereover in the third chamber 214. Similarly, the emissive layer could be cured in the fourth chamber 216 while the emissive layer is deposited on the substrate 208 in the third chamber 214, while the hole transport layer is deposited on the substrate 208 in the second chamber 212, and while the substrate 208 is nano-imprinted or laser ablated in the first chamber 210.

While only one roller 206 is shown between the chambers 210, 212, 214, and 216, it is to be understood that more rollers 206 may be present. Additionally, while the substrate 208 is depicted as traveling a linear path between the first roll 202 and the take-up roll 204, it is to be understood that the various chambers 210, 212, 214, and 216 may be disposed at different elevations and thus necessitate the substrate 208 traveling along a convoluted path.

FIG. 3 is a roll to roll coating system 300 according to another embodiment of the invention. The system 300 comprises a first roll 302 that delivers the substrate 308 to the system 300. The substrate passes over one or more rollers 306 and through one or more chambers 310, 312, 314, 316, 318, and 320 to a take-up roll 304 where the substrate 308 is wound. Prior to unrolling the substrate 308 into the system 300, the substrate 308 may have been pretreated or had other processes performed thereon. For example, the backplane of the OLED may have been created on the substrate 308.

In the system shown in FIG. 3, the substrate 308 is initially unwound from the first roll 302. The substrate 308 passes over a roller 306 before entering into the first chamber 310. Within the first chamber 310, nano-imprinting or laser ablation of the substrate 308 may occur to create an isolation bank on the substrate 308. The isolation bank on the substrate 308 permits multiple OLED structures to be produced upon the same substrate 308.

After passing through the first chamber 310, the substrate 308 passes over another roller 306 and into a second chamber 312. The second chamber 312 may comprise an inkjet chamber. Within the second chamber 312, an anode, a hole injection layer, and/or a hole transport layer may be deposited. Of course, it is to be understood that other layers may be deposited within the second chamber 312 and other processes may be performed in the second chamber 312.

After passing through the second chamber 312, the substrate 308 passes over a roller 306 and enters a third chamber 314. An emissive layer may be deposited in the third chamber 314. In one embodiment, the third chamber 314 may comprise an inkjet chamber. Of course, it is to be understood that other layers may be deposited within the third chamber 314 and other processes may be performed in the third chamber 314.

After passing through the third chamber 314, the substrate 308 passes over another roller 306 and into the fourth chamber 316. Within the fourth chamber 316, the OLED structure, and in particular the emissive layer, may be cured. In one embodiment, the curing may comprise baking the OLED structure. It is to be understood that other layers may be deposited within the fourth chamber 316 and other processes may be performed in the fourth chamber 316.

After exiting the fourth chamber 316, the substrate 308 may pass over a roller 306 and into the fifth chamber 318. In the fifth chamber 318, another layer may be deposited over the emissive layer. For example, a buffer layer and/or a transparent conductive oxide layer may be deposited over the emissive layer. Therefore, the fifth chamber 318 may comprise one or more chambers. In one embodiment, the fifth chamber 318 may comprise one or more PVD chambers. In another embodiment, the fifth chamber 318 may comprise one or more CVD chambers. In another embodiment, the fifth chamber 318 may comprise one or more PVD chambers and one or more CVD chambers.

After exiting the fifth chamber 318, the substrate 308 may pass over a roller 306 and into the sixth chamber 320. In the sixth chamber 320, another layer may be deposited over the buffer layer and/or transparent conductive layer. For example, one or more encapsulation layers may be deposited over the buffer layer and/or transparent conductive layer. Therefore, the sixth chamber 320 may comprise one or more chambers. In one embodiment, the sixth chamber 320 may comprise one or more PVD chambers. In another embodiment, the sixth chamber 320 may comprise one or more CVD chambers. In another embodiment, the sixth chamber 320 may comprise one or more PVD chambers and one or more CVD chambers.

After exiting the sixth chamber 320, the substrate 308 may be wound up on the take-up roll 304. The take-up roll 304 with the substrate 308 wound therearound may then be taken to another system for further processing if desired. In so doing, the take-up roll 304 would become the first roll in the next system.

In the roll to roll system 300, the substrate 308 may be disposed within all of the chambers 310, 312, 314, 316, 318, and 320 simultaneously and have the processes that are performed in the chambers 310, 312, 314, 316, 318, and 320 performed simultaneously. For example, if a hole transport layer is deposited on the substrate 308 in the second chamber 312, the emissive layer may be simultaneously deposited thereover in the third chamber 314. Similarly, the emissive layer could be cured in the fourth chamber 316 while the emissive layer is deposited on the substrate 308 in the third chamber 314, while the hole transport layer is deposited on the substrate 308 in the second chamber 312, while the substrate 308 is nano-imprinted and/or laser ablated in the first chamber 310, while the buffer and/or transparent conductive layers are deposited in the one or more fifth chambers 318, and while the one or more encapsulation layers are deposited in the one or more sixth chambers 320.

While only one roller 306 is shown between the chambers 310, 312, 314, 316, 318, and 320 it is to be understood that more rollers 306 may be present. Additionally, while the substrate 308 is depicted as traveling a linear path between the first roll 302 and the take-up roll 304, it is to be understood that the various chambers 310, 312, 314, 316, 318, and 320 may be disposed at different elevations and thus necessitate the substrate 308 traveling along a convoluted path.

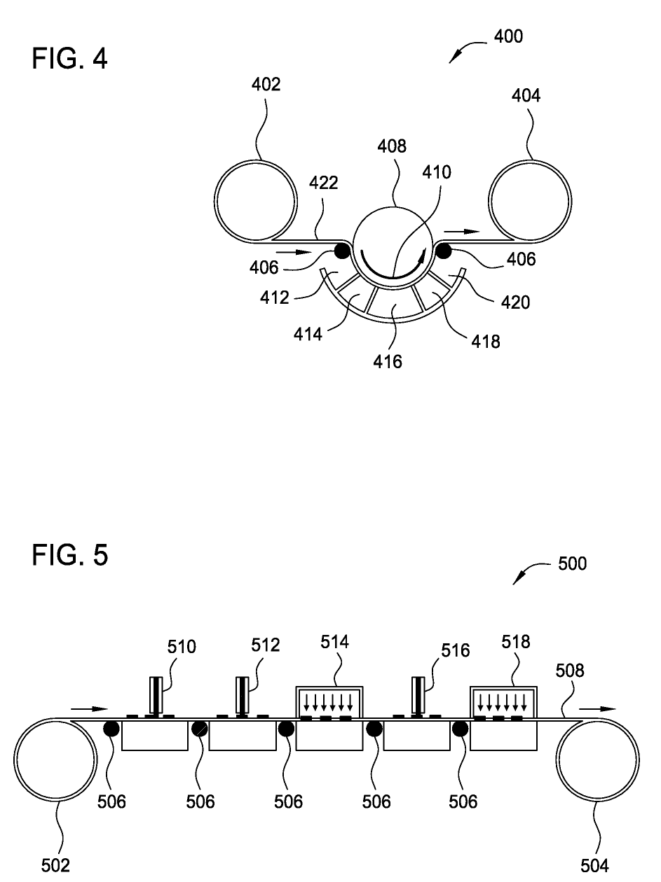

FIG. 4 is a roll to roll coating system 400 according to another embodiment of the invention. The roll to roll system 400 shown in FIG. 4 may be used for the backplane formation on the substrate 422. The substrate 422 may be fed from a first roll 402 over one or more rollers 406 and around a drum 408 that rotates as shown by arrow 410. Thereafter, the substrate 422 may be wound on a take-up roll 404. While the substrate 422 is fed around the drum 408, the substrate 422 may be exposed to one or more processes simultaneously. For example, a gate electrode or gate dielectric layer may be deposited and/or patterned in the first station 412. A source-drain metal electrode may be deposited and/or patterned in the second station 414. An indium-tin oxide pixel may be deposited onto the substrate 422 in the third station 416. A transparent conductive oxide layer may be deposited onto the substrate 422 in the fourth station 418. A buffer metal layer may be deposited in the fifth station 420. After being wound on the take-up roll 404, the substrate 422 may be taken to another system and fed into the system using the take-up roll 404 as the first roll. The take-up roll 404 may be used on other systems such as those shown in FIGS. 2, 3, and 5.

FIG. 5 is a roll to roll coating system 500 according to another embodiment of the invention. The system 500 comprises a first roll 502 that delivers the substrate 508 to the system 500. The substrate passes over one or more rollers 506 and through one or more chambers 510, 512, 514, 516, and 518 to a take-up roll 504 where the substrate 508 is wound. Prior to unrolling the substrate 508 into the system 500, the substrate 508 may have been pretreated or had other processes performed thereon. For example, the backplane of the OLED may have been created on the substrate 508.

In the system shown in FIG. 5, the substrate 508 is initially unwound from the first roll 502. The substrate passes over a roller 506 before entering into the first chamber 510. Within the first chamber 510, nano-imprinting and/or laser ablation and/or high resolution patterning of the substrate 508 may occur to create an isolation bank on the substrate 508. The isolation bank on the substrate 508 permits multiple OLED structures to be produced upon the same substrate 508.

After passing through the first chamber 510, the substrate 508 passes over another roller 506 and into a second chamber 512. The second chamber 512 may comprise an inkjet chamber. Within the second chamber 512, an anode, a hole injection layer, and/or a hole transport layer may be deposited. Of course, it is to be understood that other layers may be deposited within the second chamber 512 and other processes may be performed in the second chamber 512.

After passing through the second chamber 512, the substrate 508 passes over a roller 506 and enters a third chamber 514. The anode, hole injection layer, hole transport layer, and/or other layer may then be cured in the third chamber 514. After passing through the third chamber 514, the substrate 508 may pass over a roller 506 and into the fourth chamber 516. An emissive layer may be deposited in the fourth chamber 516. In one embodiment, the fourth chamber 516 may comprise an inkjet chamber. Of course, it is to be understood that other layers may be deposited within the fourth chamber 516 and other processes may be performed in the fourth chamber 516.

After passing through the fourth chamber 516, the substrate 508 passes over another roller 506 and into the fifth chamber 518. Within the fifth chamber 518, the OLED structure, and in particular the emissive layer, may be cured. In one embodiment, the curing may comprise baking the OLED structure. It is to be understood that other layers may be deposited within the fifth chamber 518 and other processes may be performed in the fifth chamber 518.

After exiting the fifth chamber 518, the substrate 508 may be wound up on the take-up roll 504. The take-up roll 504 with the substrate 508 wound therearound may then be taken to another system for further processing if desired. In so doing, the take-up roll 504 would become the first roll in the next system.

In the roll to roll system 500, the substrate 508 may be disposed within all of the chambers 510, 512, 514, 516, and 518 simultaneously and have the processes that are performed in the chambers 510, 512, 514, 516, and 518 performed simultaneously. For example, if a hole transport layer is deposited on the substrate 508 in the second chamber 512, the emissive layer may be simultaneously deposited thereover in the fourth chamber 516. Similarly, the emissive layer could be cured in the fifth chamber 518 while the emissive layer is deposited on the substrate 508 in the fourth chamber 516, while the hole transport layer is deposited on the substrate 508 in the second chamber 512, while the hole transport layer is cured in the third chamber 514, and while the substrate 508 is nano-imprinted or laser ablated in the first chamber 510.

While only one roller 506 is shown between the chambers 510, 512, 514, 516, and 518, it is to be understood that more rollers 506 may be present. Additionally, while the substrate 508 is depicted as traveling a linear path between the first roll 502 and the take-up roll 504, it is to be understood that the various chambers 510, 512, 514, 516, and 518 may be disposed at different elevations and thus necessitate the substrate 508 traveling along a convoluted path.

By utilizing a roll to roll coating system, OLED multiple processes may be performed upon a single substrate simultaneously. Simultaneous deposition increases substrate throughput and permits optimization of an OLED fabrication facility.

While the foregoing is directed to embodiments of the present invention, other and further embodiments of the invention may be devised without departing from the basic scope thereof, and the scope thereof is determined by the claims that follow.

1. An organic light emitting diode manufacturing apparatus, comprising:
a roll to roll substrate feed and retrieval system;
one or more inkjet deposition systems through which the substrate passes while on the roll to roll substrate feed and retrieval system; and
one or more encapsulating deposition systems through which the substrate passes while on the roll to roll substrate feed and retrieval system.

2. The apparatus of claim 1, wherein the one or more inkjet deposition systems include two inkjet deposition systems.

3. The apparatus of claim 2, further comprising one or more curing chambers, wherein the two inkjet deposition systems are separated by the one or more curing chambers.

4. The apparatus of claim 3, further comprising a physical vapor deposition chamber.

5. The apparatus of claim 4, further comprising a chemical vapor deposition chamber.

6. The apparatus of claim 5, further comprising a nano-imprinting chamber.

7. The apparatus of claim 6, further comprising a laser ablation chamber.

8. An organic light emitting diode manufacturing method, comprising:
unrolling a substrate from a first roll;
passing the substrate through a hole injection layer deposition apparatus and depositing a hole injection layer over the substrate;
passing the substrate through an emissive layer deposition apparatus and depositing an emissive layer over the hole injection layer; and
rolling the substrate onto a second roll.

9. The method of claim 8, further comprising:
passing the substrate through a curing chamber;
depositing a buffer layer over the emissive layer by physical vapor deposition.

10. The method of claim 9, further comprising:
depositing a transparent conductive oxide layer over the substrate by physical vapor deposition.

11. The method of claim 10, further comprising:
depositing an encapsulating layer over the substrate by chemical vapor deposition.

12. The method of claim 11, further comprising curing the hole injection layer.

13. The method of claim 8, further comprising:
depositing a buffer layer over the emissive layer by physical vapor deposition.

14. The method of claim 8, further comprising:
depositing an encapsulating layer over the substrate by chemical vapor deposition.

15. An organic light emitting diode manufacturing method, comprising:
depositing a hole injection layer over a substrate in a first deposition apparatus; and
depositing an emissive layer over the hole injection layer on a different region of the substrate in a second deposition apparatus separate from the first deposition apparatus while the substrate is still disposed in the first deposition apparatus.

16. The method of claim 15, further comprising curing the hole injection layer while the emissive layer is deposited on a different region of the substrate and while the hole injection layer is deposited on a different region of the substrate.

17. The method of claim 16, further comprising depositing a transparent conductive oxide over the substrate while the emissive layer is deposited on a different region of the substrate, while the hole injection layer is deposited on a different region of the substrate, and while the hole injection layer is cured in a different region of the substrate.

18. The method of claim 17, further comprising depositing an encapsulating layer over the substrate while the emissive layer is deposited on a different region of the substrate, while the hole injection layer is deposited on a different region of the substrate, while the transparent conductive oxide layer is deposited on a different region of the substrate, and while the hole injection layer is cured in a different region of the substrate.

19. The method of claim 15, further comprising depositing a transparent conductive oxide over the substrate while the emissive layer is deposited on a different region of the substrate and while the hole injection layer is deposited on a different region of the substrate.

20. The method of claim 15, further comprising depositing an encapsulating layer over the substrate while the emissive layer is deposited on a different region of the substrate and while the hole injection layer is deposited on a different region of the substrate.
